(19) United States
(12) Patent Application Publication
(10) Pub. No.: US 2022/0030146 A1
(43) Pub. Date: Jan. 27, 2022

(54) POLARIZER AND ELECTRONIC DEVICE COMPRISING THE SAME

(71) Applicant: BenQ Materials Corporation, Taoyuan (TW)

(72) Inventors: Yi Jhen Lin, Taoyuan (TW); Yu Yi Chuang, Taoyuan (TW); Hsiao Ching Chang, Taoyuan (TW); Jian Hung Wu, Taoyuan (TW); Hisn Hsing Li, Taoyuan (TW)

(21) Appl. No.: 17/015,166

(22) Filed: Sep. 9, 2020

(51) Int. Cl. H04N 5/225; G02B 5/30; H01L 27/32; H01L 51/52

(52) U.S. Cl. CPC H04N 5/2257; H01L 51/5293; H01L 27/3234; G02B 5/3025

(57) ABSTRACT

The invention discloses a polarizer comprising a first protective layer, a second protective layer, and a polarizing layer sandwiched therebetween. The polarizing layer comprises a first polarizing area and a second polarizing area with different polarizations. The polarization degree of the first polarizing area is greater than 99.9% and less than 100%, and the light transmittance is between 40% and 45%; the polarization degree of the second polarizing area is not less than 90% and not greater than 99.9%, and the light transmittance is between 45% to 48%. The disclosed polarizer can be used in an electronic device with an integrated camera module.

### CROSS-REFERENCE TO RELATED APPLICATION

This application claims the priority benefit of Taiwanese Invention Application Serial Number 109124611, filed on Jul. 21, 2020, which is incorporated herein by reference.

### TECHNICAL FIELD

The present invention relates to a polarizer, and more particularly to a polarizer for electronic device and an electronic device with the same.

### BACKGROUND OF THE INVENTION

In recent years, various electronic devices ,such as personal computers, mobile communication devices and wearable devices have been widely used, and input elements or/and output elements, such as displays, touch panels, sensors and camera modules assembled with more than one on electronic devices in a limited space have become the focus of related technical development. At present, the structural design of electronic devices with displays integrated with camera modules has become the mainstream in the market. As shown in the schematic top view of FIG. 1, a conventional electronic device 100 with a display 15 integrated with a camera module 14 is illustrated. In order to prevent the camera module 14 from being visible from the outside of the electronic device, the camera module 14 will be assembled under the frame 18 of the display area 15. However, as the display area 15 of the electronic device is further maximized, the camera module 14 will also be integrated into the display area 15. FIGS. 2A and 2B are respectively a cross-sectional view and top/bottom views of an conventional electronic device 2a comprising an integrated camera module 24 and a display module 200. As shown in FIG. 2A, the camera module 24 of the electronic device 2a is installed in the display module 200, and the hollow area is formed in the polarizing plate 22 and the display element 23 by mechanical shape cutting or drilling, to accommodate the camera module 24 and enable the camera lens 21 to achieve the photography function without being shielded. This type of electronic device 2a has a camera module functional zone 26 in the display area 25, which occupies a part of the display area 25 and reduces the display ratio of the display area 25 of the display module 200. Therefore, optimizing the assembly form of the camera module to increase the display ratio of display module has become one of the key points of technological improvement of current manufacturers of electronic devices.

With the development of OLED display technology, the feasibility of assembling camera modules under the display and increasing the display ratio of the display has been proposed in related technologies. FIG. 3A and 3B are respectively a cross-sectional view and a schematic top view of a conventional electronic device with an OLED display integrated with a camera module. As shown in FIG. 3A and 3B, the electronic device 3a comprises an OLED display module 300 and a camera module 34, wherein the camera module 34 is assembled under the OLED display module 300 including a polarizer 32 and an OLED display element 33, to achieve the full-screen display in the display area 35 of the electronic device 3a. In order to prevent the light sensitivity of the lens 31 of the camera module 34 from being affected by the polarization characteristics of the polarizer 32 on the OLED display module 33, thereby degrading the photographic quality, the lens 31 of the camera module 35 must be matched with a depolarization area 32b on the polarizer 32. However, when the photographing function of the camera module 35 under the depolarization area 32b is not activated, the non-polarization of the area makes the display quality be degraded when this area is used for displaying, and the high light transmittance of the depolarization area 32b cause the lens 31 visible from the outside of the electronic device 3a.

Therefore, there is a need for a solution that can integrate a camera module into a display module and hide the camera lens of the camera module from outside of electronic device.

### SUMMARY OF THE INVENTION

An object of the present invention is to provide a polarizer suitable for a electronic device integrated a camera module with a display, which enables the electronic device to display in full-screen and hide the camera lens of the camera module from outside of the electronic device and provide both excellent quality of photography and display. The present invention discloses a polarizer for electronic devices, comprising a first protective film, a polarizing film and a second protective film. Wherein, the polarizing film is arranged between the first protective film and the second protective film, and the polarizing film comprises a first polarizing zone and a second polarizing zone, wherein the polarization degree of the first polarizing zone is greater than 99.9% and less than 100%, and the light transmittance thereof is ranging between 40% and 45%; the polarization degree of the second polarization zone is not less than 90% and not more than 99.9%, preferably not less than 91% and not more than 98%, and the light transmittance thereof is ranging between 45% and 48%.

A further object of the present invention is to provide an electronic device, comprising a display element, the display element further comprises a display area, a polarizer arranged on the display element and a camera module integrated into the display element, wherein the display area comprises a functional zone of the camera module, and the polarizer comprises a first polarization zone and a second polarization zone, wherein the polarization and light transmittance of the first polarization zone and the second polarization zone are different, and the second polarization zone is located on the functional zone of the camera module.

In a preferred embodiment of electronic device of the present invention, the second polarization zone can substantially completely cover the functional zone of the camera module.

In a preferred embodiment of electronic device of the present invention, as mentioned above, the polarization degree of the second functional zone of the polarizer is not less than 90% and not more than 99.9%, preferably not less than 91% and not more than 98%, and the light transmittance thereof is between 45% and 48%.

In a preferred embodiment of electronic device of the present invention, the first polarization zone covers the display area excluding the functional zone of the camera module, wherein the polarization degree of the first polarization zone of the polarizer is greater than 99.9% and less than 100%, and the light transmittance thereof is between 40% and 45%.

The above and other aspects of the invention will become better understood with regard to the following detailed description of the preferred but non-limiting embodiment(s). These and other aspects of the invention will become apparent from the following description of the presently preferred embodiments. The detailed description is merely illustrative of the invention and does not limit the scope of the invention, which is defined by the appended claims and equivalents thereof. As would be obvious to one skilled in the art, many variations and modifications of the invention may be affected without departing from the spirit and scope of the novel concepts of the disclosure.

### BRIEF DESCRIPTION OF THE DRAWINGS

FIG. 1 is a schematic cross-sectional view of a conventional electronic device with a display integrated with a camera module 11.

FIG. 2A and 2B are respectively a schematic cross-sectional view and schematic top/bottom views of a conventional electronic device with a display integrated with a camera module.

FIG. 3A and 3B are respectively a schematic cross-sectional view and a schematic top view of a conventional electronic device with an OLED display integrated with a camera module.

FIG. 4 is a schematic cross-sectional view of a polarizer 42 suitable for electronic devices drawn according to an embodiment of the present invention.

FIG. 5 is a schematic view of a method for manufacturing a polarizing film 422 drawn according to an embodiment of the present invention.

FIG. 6A, 6B, and 6C are respectively schematic cross-sectional views and a schematic top view of an electronic device comprising a polarizer 42, a display element 63a or 63b, and a camera module 64a or 64b drawn according to an embodiment of the present invention.

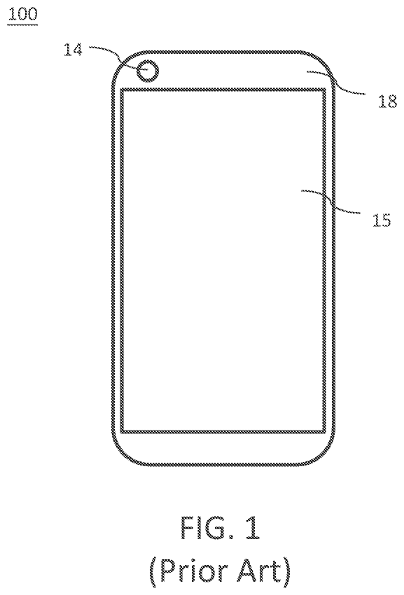

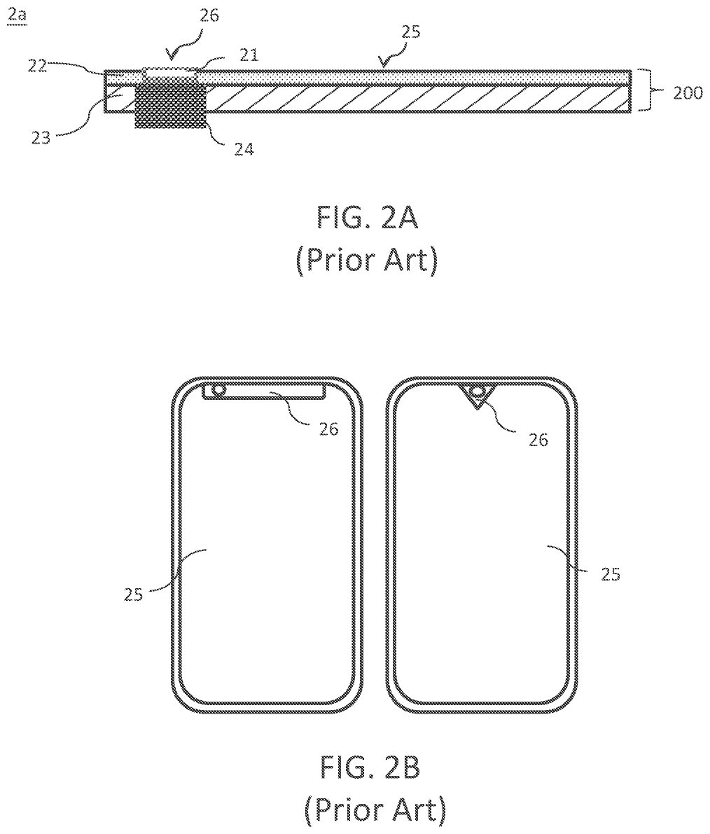

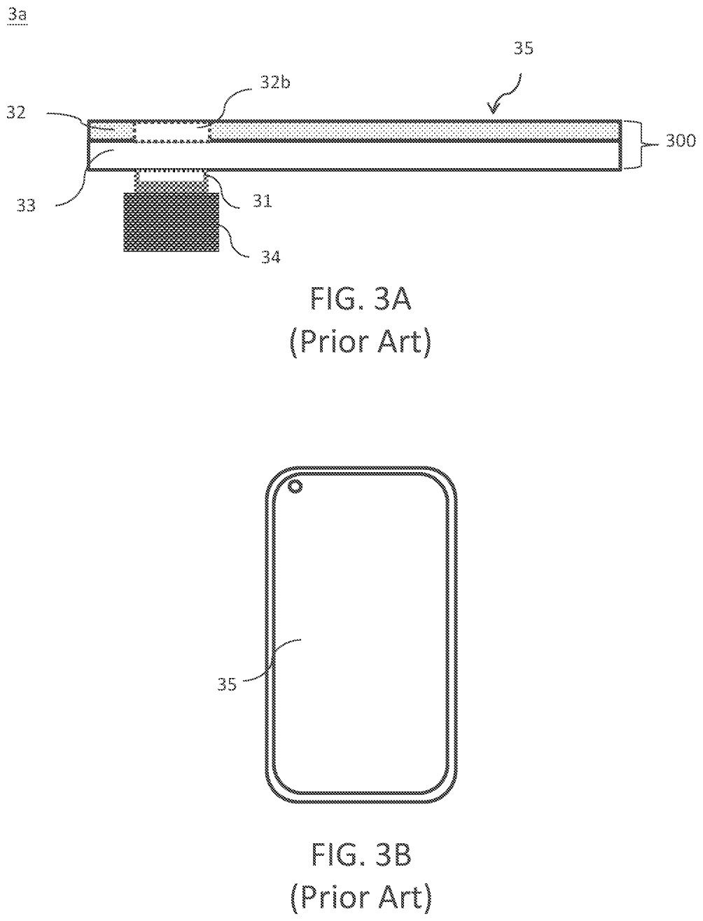

### DETAILED DESCRIPTION OF THE INVENTION

In the following detailed description, for purposes of explanation, numerous specific details are set forth in order to provide a thorough understanding of the disclosed embodiments. It will be apparent, however, that one or more embodiments may be practiced without these specific details.

It is apparent that departures from specific designs and methods described and shown will suggest themselves to those skilled in the art and may be used without departing from the spirit and scope of the invention. The present invention is not restricted to the particular constructions described and illustrated, but should be construed to cohere with all modifications that may fall within the scope of the appended claims.

Unless defined otherwise, all technical and scientific terms used herein have the same meaning as commonly understood by one of ordinary skill in the art to which this invention belongs. Generally, the nomenclature used herein and the laboratory procedures are well known and commonly employed in the art. Conventional methods are used for these procedures, such as those provided in the art and various general references. Where a term is provided in the singular, the inventors also contemplate the plural of that term. The nomenclature used herein and the laboratory procedures described below are those well-known and commonly employed in the art.

The term “light transmittance” used herein refers to the ratio of the intensity of the transmitted visible light through the polarizer to the original incident visible light. The term “polarization degree” refers to, after the light passes through the polarizer, the ratio of the intensity difference of the visible light parallel to the absorption axis and the visible light perpendicular to the absorption axis to the intensity of the transmitted visible light.

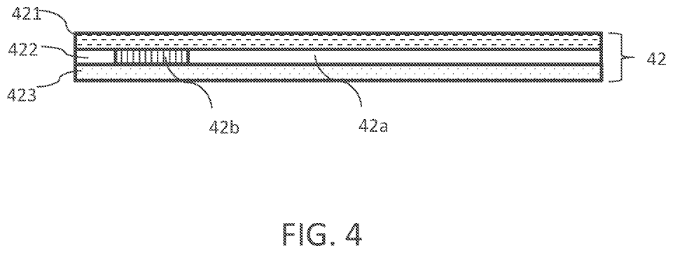

The following figures illustrate the present polarizer for electronic devices. As shown in FIG. 4, the present polarizer 42 sequentially comprises a first protective film 421, a polarizing film 422 and a second protective film 423, and the polarizing film 422 comprises a first polarizing zone 42a and a second polarizing zone 42b.

In an embodiment of the present invention, the suitable polarizing film 422 can be a polarizer commonly used in the related art, such as, but not limited to an iodine-based polarizer, a dye-based polarizer, a polyvinylidene-based polarizer or the combinations thereof.

In an embodiment of the present invention, the first protective film 421 and the second protective film 423 are used to protect and support the polarizing film 422. Therefore, a suitable material can be a film with good mechanical strength and light transmittance, such as, but not limited to polymethylmethacrylate (PMMA), polyethylene terephthalate (PET), polyethylene naphthalate (PEN), polycarbonate (PC), triacetyl cellulose (TAC), polyimide (PI), polyethylene (PE), polypropylene (PP), polyvinyl alcohol (PVA), polyvinyl chloride (PVC) or cyclic olefin copolymer (COC). The polarizer 42 can further comprises a functional coating film to provide the surface characteristics required by the electronic device, wherein the functional coating film can be a scratch-resistant coating film, an anti-reflection film, an anti-glare film, an anti-reflection-anti-glare film, an oleophobic film or combinations thereof.

In another embodiment of the present invention, the second protective film 423 can be a functional optical film, for example, a retardation film.

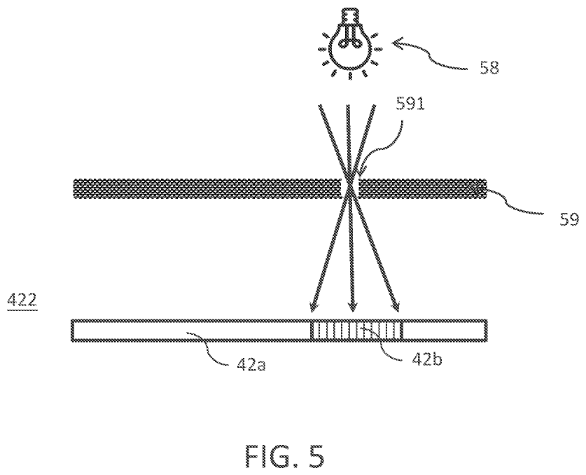

The suitable polarizer for an electronic device is a iodine-based polarizer, a dye-based polarizer or a polyvinylidene-based polarizer with the polarization degree of greater than 99.9% and less than 100%, and the light transmittance thereof is ranging between 40% and 50%. The method of preparing the present polarizer can be performed by partially depolarizing the polarizer suitable for electronic devices, such as light-exposing treatment or chemical treatment. FIG. 5 is a schematic diagram illustrating a method of preparing the first polarizing zone 42a and the second polarizing zone 42b of the polarizing film 422 of the present invention. As shown in FIG. 5, the polarizing film 422 is shielded by an opaque mask 59 with an aperture 591 of an appropriate size , and illuminated with a light source 58 with an adjusted irradiation energy to form the second polarization zone 42b thereon. In the illuminating step, the light source 58 is the one that can provide appropriate irradiation intensity, and the suitable light sources can be, but are not limited to, a low-pressure mercury vapor lamp, a medium-pressure mercury vapor lamps, a high-pressure mercury vapor lamps, an ultra-high-pressure mercury vapor lamps, a chemical lamps, a Wood's lamps, an electrodeless discharge lamps or a metal halide lamps, and the suitable irradiation wavelength is ranging between 200 nm and 1000 nm and preferably the irradiation intensity is ranging between 0.5 kW/cm² and 5.9 kW/cm². The cumulative light quantity of the product of the above-mentioned irradiation intensity and irradiation time is preferably ranging between 20 J/cm² and 140 J/cm². In the embodiments of the present invention, the shape of the second polarization zone 42b is not limited, and it can be a regular shape or an irregular shape, as long as it corresponds to the shape of the functional zone.

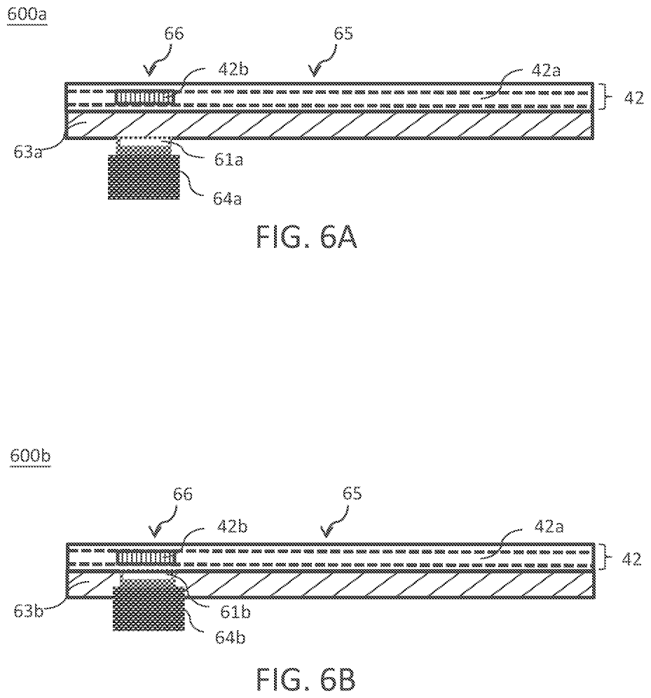

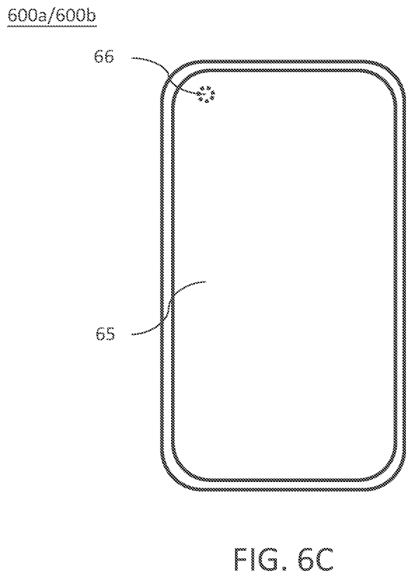

FIG. 6A is a schematic cross-sectional view illustrating an electronic device 600a integrated with a camera module 64a according to an embodiment of the present invention, which comprises a display element 63a, a polarizer 42, and a camera module 64a integrated with the display element 63a and equipped with a lens 61; FIG. 6B is a schematic cross-sectional view illustrating an electronic device 600b integrated with a camera module 64b according to anther embodiment of the present invention, which comprises a display element 63b, a polarizer 42, and a camera module 64b integrated with the display element 63b and equipped with a lens 61; FIG. 6C is the schematic top view of the electronic device 600a or 600b. The display element 63a or 63b comprises a display area 65, and the display area 65 further comprises a functional zone of the camera module 66 corresponding to the lens 61a or 61b of the camera module 64a or 64b, thereby the camera module 64a or 64b can be effectively photosensitive to complete the photographic action. Wherein the polarizer 42 covers the display area 65, the polarizer 42 comprises a first polarizing area 42a and a second polarizing area 42b with different polarization degrees and light transmittances, and the second polarizing area 42b is located on the functional zone of the camera module 66, and the first polarization zone covers the display area 65 excluding the functional zone of the camera module 66. In a preferred embodiment of the present invention, the second polarization zone 42b can substantially and completely cover the functional zone of the camera module 66 of the display area 65. In the preferred embodiments of the present invention, the polarization degree of the second polarization zone 42b is not less than 90% and not more than 99.9%, preferably not less than 91% and not more than 98%, and the light transmittance thereof is ranging between 45% and 48%; the polarization degree of the first polarizing zone 42a is greater than 99.9% and less than 100%, and the light transmittance thereof is ranging between 40% and 45%.

The specific light transmittance of second polarization zone 42b of the polarizer 42 provides the effective photosensitivity of the corresponding functional zone of the camera module 66, which further enable the camera module 64a or 64b to complete the photographic action, and the high polarization degree of first polarization zone 42a enable the corresponding display area 65 excluding functional zone of the camera module 66 to obtain an excellent display quality. In the assembly of electronic device 600a, the camera module 64a including the lens 61a is integrated and disposed under the display element 63a, when the camera module 64a that correspond with the second polarization zone 24b is not activated, the specific polarization degree of second polarization zone 42b enables this area to obtain an excellent display quality, and also makes the camera lens 61 hidden from the outside of electronic device 600a.

In an embodiment of the present invention, the display element 11 can be the one known in the related art, such as, but not limited to an LED display element, an LCD display element, an OLED display element or combinations thereof.

According to the present polarizer suitable for electronic devices integrating a camera module into display, comprising a first polarization zone and a second polarization zone with different polarization degrees and transmittances, which achieves the electronic device to display in full-screen, can hide the camera lens from the outside of electronic device and provide both excellent quality of photography and display when the polarizer is applied to an electronic device.

The detailed description is merely illustrative of the invention and does not limit the scope of the invention, which is defined by the appended claims and equivalents thereof. As would be obvious to one skilled in the art, many variations and modifications of the invention may be affected without departing from the spirit and scope of the novel concepts of the disclosure.

What is claimed is:

1. A polarizer, comprising:
a first protective film;
a second protective film; and
a polarizing film arranged between the first protective film and the second protective film, comprising a first polarizing zone and a second polarizing zone;
wherein the polarization degree of the first polarizing zone is greater than 99.9% and less than 100%, and the light transmittance thereof is ranging between 40% and 45%;
wherein the polarization degree of the second polarization zone is not less than 90% and not more than 99.9%, and the light transmittance thereof is ranging between 45% and 48%.

2. An electronic device, comprising:
a display element comprising a display area;
a polarizer arranged on the display element; and
a camera module integrated into the display element, wherein the display area comprises a functional zone of the camera module;
wherein the polarizer comprises a first polarization zone and a second polarization zone, and the polarization and light transmittance of the first polarization zone and the second polarization zone are different, and the second polarization zone is located on the functional zone of the camera module.

3. The electronic device as claimed in claim 2, wherein the second polarization zone substantially and completely covers the functional zone of the camera module.

4. The electronic device as claimed in claim 2, wherein the polarization degree of the second functional zone of the polarizer is not less than 90% and not more than 99.9%, and the light transmittance thereof is between 45% and 48%.

5. The electronic device as claimed in claim 2, wherein the polarization degree of the first polarization zone of the polarizer is greater than 99.9% and less than 100%, and the light transmittance thereof is between 40% and 45%, and the first polarization zone covers the display area excluding the functional zone of the camera module.
